(19) United States
(12) Patent Application Publication
(10) Pub. No.: US 2008/0200027 A1
(43) Pub. Date: Aug. 21, 2008

(54) METHOD OF FORMING METAL WIRE IN SEMICONDUCTOR DEVICE

(76) Inventor: Jik Ho Cho, Anyang-si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/962,524

(22) Filed: Dec. 21, 2007

(30) Foreign Application Priority Data
Feb. 15, 2007 (KR) 2007-15904

(51) Int. Cl. H01L 21/4763

(52) U.S. Cl. 438/653; 257/E21.495

(57) ABSTRACT

The present invention discloses a method of forming a metal wire in a semiconductor device and comprises the steps of forming a first insulating layer, a conductive layer and a capping layer on a semiconductor substrate, forming hard mask patterns on the capping layer, etching the capping layer and the conductive layer through an etching process utilizing the hard mask patterns to form metal wires, removing the hard mask patterns and forming a second insulating layer on the semiconductor substrate including the metal wires to insulate the metal wires from each other.

### CROSS-REFERENCE TO RELATED APPLICATIONS

The priority of Korean Patent Application No. 2007-15904 filed on Feb. 15, 2007, is hereby claimed and the contents thereof are hereby incorporated herein by reference in its entirety.

### BACKGROUND OF THE INVENTION

The present invention relates to a method of forming a metal wire in a semiconductor device, and more particularly relates to a method of forming a metal wire in a semiconductor device for preventing resistance of a metal wire from being increased.

In flash memory devices, a metal wire is formed by means of a damascene structure which is favorable to the aspects of a simplification of the manufacturing process and a defect management. However, as the device becomes highly integrated to obtain a width of metal wire of 60 nm or less, the metal wires are formed through a reactive ion etching (RIE) scheme to realize a low resistance and low capacitance of the metal wire having less width.

In recent times, due to a miniaturization of the pattern used in an etching process for forming the metal wires, an exposure equipment in which KrF (krypton fluorine) light source is employed has been substituted for an exposure equipment in which ArF (argon fluorine) light source is employed. Due to a substitution of the exposure equipment, thickness of a photoresist layer should be reduced. If the conventional photoresist scheme is applied, however, the photoresist layer having a reduced thickness is damaged, thereby causing a change of a profile of the device. To prevent the above-described problems from being generated, a hard mask layer for the metal wires is formed, in which an amorphous carbon layer is formed on a conductive layer.

However, the amorphous carbon layer should be removed in a process for removing the photoresist layer and a cleaning process, and a process of forming an insulating layer for isolating the metal wires from each other should be carried out in a state where the amorphous carbon layer is removed. At this time, a high density plasma (HDP) oxide layer is utilized as the insulating layer. If the high density plasma (HDP) oxide layer is utilized as the insulating layer, a sputtering method by which a bias is applied to a susceptor region on which a wafer is placed to generate an ion bombardment effect is utilized. Due to the above-described sputtering method, some of an upper portion of the metal wire is damaged, and deposition gas can is enter in the metal wire through a damaged area of the metal wire, thereby increasing a specific resistance of the metal wire.

In addition, during the sputtering method, atoms of tungsten (W) constituting the metal wire are re-deposited between the metal wires to form a bridge connecting the metal wires.

### SUMMARY OF THE INVENTION

Since the sputtering method is utilized in the process for forming the insulating layer to isolate the metal wires from each other, some of the metal wire is damaged by an impact of accelerated ions having high energy. In the method of the present invention, however, a capping layer is formed on the metal wire, and so it is possible to prevent the metal wire from being damaged.

A method of forming a metal wire in a semiconductor device according to one embodiment of the present invention comprises the steps of forming a first insulating layer, a conductive layer and a capping layer on a semiconductor substrate, forming hard mask patterns on the capping layer, etching the capping layer and the conductive layer through an etching process utilizing the hard mask patterns to form metal wires, removing the hard mask patterns, and forming a second insulating layer on the semiconductor substrate including the metal wires to insulate the metal wires from each other.

In a preferred embodiment, a barrier metal layer is further formed between the first insulating layer and the conductive layer. The capping layer preferably is formed of a silicon nitride (SiN) layer, a silicon oxide (SiO₂) layer or a silicon oxynitride (SiON) layer. The capping layer preferably has a thickness in a range of 100 Å to 1,000 Å. The hard mask pattern preferably has a stacked structure consisting of an amorphous carbon layer and a silicon oxynitride layer.

The second insulating layer is formed through a sputtering method and preferably is formed of a high density plasma (HDP) oxide layer. During the process for forming the second insulating layer, an upper portion of the capping layer optionally can be partially damaged by a sputtering method

### BRIEF DESCRIPTION OF THE DRAWINGS

The above-described and other features and advantages of the present invention will become readily apparent by reference to the following detailed description when considered in conjunction with the accompanying drawings wherein:

FIG. 1A to FIG. 1D are sectional views of a semiconductor device for illustrating a method of forming a metal wire in a semiconductor device according to an embodiment of the present invention.

### DESCRIPTION OF SPECIFIC EMBODIMENTS

Hereinafter, the preferred embodiment of the present invention will be explained in more detail with reference to the accompanying drawings.

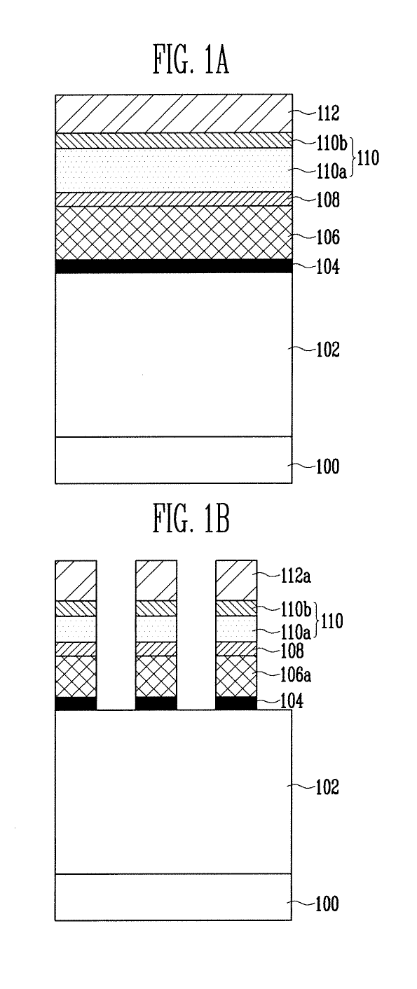

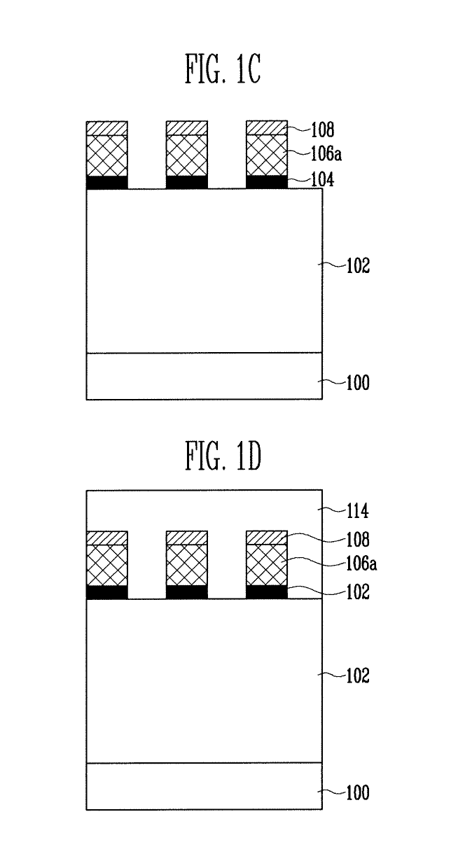

FIG. 1A to FIG. 1D are sectional views of a semiconductor device for illustrating a method of forming a metal wire in a semiconductor device according to an embodiment of the present invention.

Referring to FIG. 1A, a first insulating layer 102 is formed on a semiconductor substrate 100 on which predetermined structures such as an isolation layer, a transistor, a source contact plug and the like are formed, and the first insulating layer 102 is then etched to form a contact hole (not shown). To reduce a contact resistance, an ion implanting process is executed to from a junction area (not shown) in the semiconductor substrate 100, and a heat treatment process is then performed to activate the implanted ions.

Subsequently, a first barrier metal layer (not shown) is formed in the contact hole and a first conductive layer is then formed on the semiconductor substrate 100 including the contact hole to fill the contact hole. In this embodiment, the first conductive layer is formed of a tungsten (W) layer. A chemical mechanical polishing (CMP) process is performed until an upper portion of the first insulating layer 102 is exposed, to form a contact plug (not shown).

Then, a second barrier metal layer 104, a second conductive layer 106 for a metal wire and a capping layer 108 are sequentially formed on the first insulating layer 102. In this embodiment, the second conductive layer 106 is formed of a tungsten (W) layer and the capping layer 108 preferably is formed of a silicon nitride (SiN) layer, a silicon oxide (SiO₂) layer or a silicon oxynitride (SiON) layer. To prevent the capping layer from being damaged through a sputtering method and reaction gas from being flowed in the metal wire during a subsequent process of forming a second insulating layer, the capping layer preferably has a thickness in a range of 100 Å to 1,000 Å.

Subsequently, a hard mask layer 110 and a photoresist layer 112 are formed on the capping layer 108. In this embodiment, the hard mask layer 110 has a stacked structure consisting of an amorphous carbon layer 110a and a silicon oxynitride (SiON) layer 110b.

Referring to FIG. 1B, the photoresist layer 112 is etched through an exposure process and a developing process to form photoresist patterns 112a, and the hard mask layer 110 is then etched by means of the photoresist patterns 112a acting as an etching mask. The capping layer 108, the second conductive layer 106 and the second barrier metal layer 104 are etched by means of the photoresist patterns 112a and the etched hard mask layer 110 acting as the etching mask to form metal wires 106a.

Referring to FIG. 1C, after removing the photoresist patterns 112a, a cleaning process is performed to remove the hard mask layer 110.

Referring to FIG. 1D, to isolate the metal wires 106a from each other a second insulating layer 114 is formed on the semiconductor substrate 100 including the metal wires 106a. In this embodiment, the second insulating layer 114 is formed through a sputtering method and formed of a high density plasma (HDP) oxide layer.

Since the sputtering method is utilized in the process for forming the second insulating layer 114, some of upper portion of the capping layer 108 is damaged due to an impact of accelerated ions with high energy. However, the metal wires 106a are not damaged by the capping layer 108. Due to the above-described phenomenon, it is possible to prevent resistance of the metal wire 106 from being increased. In addition, since the capping layer 108 remains on the metal wire 106, it is possible to inhibit reaction gas used in the process for forming the second insulating layer 114 from flowing to the metal wires 106a.

Further, in a case where the capping layer is not formed on the metal wires 106a, atoms of tungsten (W) are re-deposited between the metal wires 106a by a sputtering method during a process for forming the second insulating layer 114 to form bridges connecting the metal wires 106a. Due to the capping layer 108 formed on the metal wires 106a, however, it is possible to prevent the above-described bridges from being formed.

The present invention as described above has one or more of the advantages as follows.

First, since the sputtering method is utilized in the process for forming the second insulating layer, some of the upper portion of the capping layer is damaged by an impact of accelerated ions with high energy. However, because of the capping layer formed on the metal wires, it is possible to prevent the metal wire from being damaged.

Second, since damage of the metal wires is prevented by the capping layer when the second insulating layer is formed, it is possible to prevent resistance of the metal wire from being increased.

Third, since the capping layer remains on the metal wires, it is possible to inhibit the reaction gas utilized in the process for forming the second insulating layer from flowing to the metal wires.

Although embodiments have been described with reference to a number of illustrative embodiments thereof, it should be understood that numerous other modifications and embodiments can be devised by those skilled in the art that will fall within the spirit and scope of the principles of the invention. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming a metal wire in a semiconductor device, comprising the steps of:
forming a first insulating layer, a conductive layer and a capping layer on a semiconductor substrate;
forming hard mask patterns on the capping layer;
etching the capping layer and the conductive layer through an etching process utilizing the hard mask patterns, to form metal wires;
removing the hard mask patterns; and
forming a second insulating layer on the semiconductor substrate including the metal wires to insulate the metal wires from each other.

2. The method of forming a metal wire in a semiconductor device of claim 1, further comprising the step of forming a barrier metal layer between the first insulating layer and the conductive layer.

3. The method of forming a metal wire in a semiconductor device of claim 1, comprising forming the capping layer of a silicon nitride (SiN) layer, a silicon oxide (SiO₂) layer or a silicon oxynitride (SiON) layer.

4. The method of forming a metal wire in a semiconductor device of claim 1, comprising forming the capping layer to a thickness in a range of 100 Å to 1,000 Å.

5. The method of forming a metal wire in a semiconductor device of claim 1, wherein the hard mask patterns have a stacked structure consisting of an amorphous carbon layer and a silicon oxynitride layer.

6. The method of forming a metal wire in a semiconductor device of claim 1, comprising forming the second insulating layer through a sputtering method.

7. The method of forming a metal wire in a semiconductor device of claim 1, comprising forming the second insulating layer of a high density plasma (HDP) oxide layer.
